(19) United States
(12) Patent Application Publication
(10) Pub. No.: US 2001/0004117 A1
(43) Pub. Date: Jun. 21, 2001

(54) Photodiode and method of manufacturing same

(76) Inventors: Mari Chikamatsu, Tokyo (JP); Nobuyuki Nagashima, Tokyo (JP)

Correspondence Address: SUGHRUE, MION, ZINN,, MACPEAK & SEAS, 2100 Pennsylvania Avenue, N.W., Washington, DC, 20037-3202, US

(21) Appl. No.: 09/726,315

(22) Filed: Dec. 1, 2000

(30) Foreign Application Priority Data
Dec. 15, 1999 (JP) 11-355731
Jul. 27, 2000 (JP) 2000-226684

(51) Int. Cl. H01L 27/148; H01L 29/768

(52) U.S. Cl. 257/229

(57) ABSTRACT

A photodiode includes a semiconductor region (1, 7) having a first conductivity type (p or n type), an embedded layer (2) disposed in the semiconductor region (1, 7) and having a second conductivity type (n or p type) different from the first conductivity type (p or n type), and a leader (9) made of a semiconductor of the second conductivity type (n or p type). The embedded layer extends parallel to a surface (8) of the semiconductor region (1, 7). The leader extends from the surface (8) of the semiconductor region (1, 7) along the depth of the semiconductor region (7, 7) and is joined to a region of the embedded layer (2). The photodiode preferably has a base layer (11) made of a semiconductor of the second conductivity type (n or p type). The base layer (11) is held against the surface (8) of the semiconductor region (1, 7) and extends parallel to the surface (8) of the semiconductor region (1, 7). The base layer is isolated from the embedded layer (2) and electrically connected to the leader (9).

### BACKGROUND OF THE INVENTION

1. Field of the Invention

The present invention relates to a photodiode and a method of manufacturing a photodiode, and more particularly to a photodiode having a high quantum efficiency and a method of manufacturing such a photodiode.

2. Description of the Related Art

Usually, photodiodes are used to detect light. One such photodiode is disclosed in Japanese laid-open patent publication No. 7-15028. As shown in FIG. 1 of the accompanying drawings, the disclosed photodiode has semiconductor substrate 101 made of a p-type conductor doped with a dopant of a relatively high concentration. Since semiconductor substrate 101 functions as an electrode of the photodiode, the concentration of the dopant in semiconductor substrate 101 must be high.

The photodiode also has first layer 102 joined to an upper surface of semiconductor substrate 101 and having a p-type conductivity. First layer 102 is doped with a dopant which has a concentration lower than the concentration of the dopant in semiconductor substrate 101. Second layer 103 having an n-type conductivity is joined to an upper surface of first layer 102. Second layer 103 is doped with a dopant whose concentration decreases toward the interface between first layer 102 and second layer 103. Oxide layer 104 is joined to an upper surface of second layer 103 and contains a doped impurity having an n-type conductivity. To semiconductor substrate 101 and second layer 103, there are connected respective connectors 105, 106 which are electrically connected to an external circuit.

Photodiodes detect light with a depletion layer which is present mainly in the vicinity of the junction surface of a pn junction. In the disclosed photodiode, first layer 102 and second layer 103 make up such a pn junction therebetween. When light is applied to the photodiode, the depletion layer produces electron and hole pairs as a current which is detected as representing the applied light.

Semiconductor substrate 101 of the disclosed semiconductor has a high impurity concentration of about 1×10¹⁸ cm⁻³. The photodiode is manufactured according to a fabrication process including a high-temperature heating step. When heated in the high-temperature heating step, the dopant is diffused from the semiconductor substrate 101 into first layer 102 that serves as a photodetector, increasing the dopant concentration in first layer 102. When the dopant concentration in first layer 102 is increased, the width of the depletion layer formed in the vicinity of the interface between first layer 102 and second layer 103 is reduced. The reduced width of the depletion layer which detects light causes a problem in that it lowers the quantum efficiency. For this reason, there has been a demand for a photodiode having a high quantum efficiency.

### SUMMARY OF THE INVENTION

It is an object of the present invention to provide a photodiode having a high quantum efficiency.

Another object of the present invention is to provide a photodiode which has a high response speed.

Still another object of the present invention is to provide a photodiode having a high quantum efficiency and a high response speed.

In the summarized description of a photodiode and a method of manufacturing a photodiode according to the present invention, various components are denoted by numerals and characters in parenthesis. Those numerals and characters correspond to reference numerals and characters applied to various components according to at least one of embodiments of the present invention, or particularly, various components illustrated in drawings corresponding to at least one of embodiments of the present invention. Those numerals and characters are clearly indicative of an association between the claimed components and the illustrated component in the embodiments. However, such an association should not be interpreted to limit the claimed components to the illustrated component in the embodiments.

According to the present invention, there is provided a photodiode comprising a semiconductor region (1, 7, 31, 33) having a first conductivity type (p or n type), an embedded layer (2, 32) disposed in the semiconductor region (1, 7, 31, 33) and having a second conductivity type (n or p type) different from the first conductivity type (p or n type), and a leader (9, 35) made of a semiconductor of the second conductivity type (n or p type). The embedded layer (2, 32) extends parallel to a surface (8, 34) of the semiconductor region (1, 7, 31, 33). The leader (9, 35) extends from the surface (8, 34) of the semiconductor region (1, 7, 31, 33) along the depth of the semiconductor region, and is joined to a region of the embedded layer (2, 32). Since the interior of the semiconductor region (1, 7, 31, 33) serves as a depletion layer, the photodiode has a high quantum efficiency.

The photodiode may further have a base layer (11) made of a semiconductor of the second conductivity type (n or p type). The base layer (11) is held against the surface (8) of the semiconductor region (1, 7) and extends parallel to the surface (8) of the semiconductor region (1, 7). The base layer (11) is isolated from the embedded layer (2) and electrically connected to the leader (9). The base layer (11) allows a depletion layer to extend from the surface of the semiconductor region (1, 7) along the depth thereof when a bias is applied. With this depletion layer in addition to the depletion extending from the embedded layer (2), the entire portion of the semiconductor region (1, 7) which is sandwiched between the base layer (11) and the embedded layer (2) is turned into a depletion layer.

The distance between the surface (8) of the semiconductor region (1, 7) and the embedded layer (2) should preferably be determined depending on an absorption coefficient with respect to light applied to the semiconductor region. Depending on the absorption coefficient, the distance between the surface (8) of the semiconductor region (1, 7) and the embedded layer (2) is determined to increase a quantum efficiency or reduce a portion of semiconductor region which does not contribute to the detection of light. The distance between the surface (8) of the semiconductor region (1, 7) and the embedded layer (2) should preferably be represented by 1/α where a represents the absorption coefficient. The distance thus selected is effective to increase the quantum efficiency.

The semiconductor region (1, 7), the embedded layer (2), and the base layer (11) have respective dopant concentrations selected to cause a space between the embedded layer (2) and the base layer (11) to serve as a depletion layer in its entirety. The dopant concentrations are determined depending on a distance between the base layer (11) and the embedded layer (2). The space between the embedded layer (2) and the base layer (11) is depleted for achieving a high quantum efficiency.

The photodiode may further comprise at least one second embedded layer (13) having the second conductivity type (n or p type). The second embedded layer (13) is disposed in the semiconductor region (1, 7) and extends parallel to the surface (8) of the semiconductor region (1, 7). The second embedded layer (13) is isolated from the embedded layer (2) and the base layer (11) and joined to the leader (9). This arrangement increases the volume of the depletion layer for a high quantum efficiency.

The semiconductor region (1, 7), the embedded layer (2), the second embedded layer (13), and the base layer (11) have respective dopant concentrations selected to cause a space between the embedded layer (2) and the second embedded layer (13), a space between a plurality of the second embedded layers (13), and a space between the second embedded layer (2) and the base layer (11) to serve as depletion layers in their entirety. In this manner, the space between the embedded layer (2) and the second embedded layer (13), the space between a plurality of the second embedded layers (13), and the space between the second embedded layer (2) and the base layer (11) are depleted for a high quantum efficiency.

The photodiode may further comprise another base layer (36) made of a semiconductor of the first conductivity type (p or n type). The other base layer (36) is held against the surface (34) of the semiconductor region (31, 33) and extends parallel to the surface (34) of the semiconductor region (31, 33). The other base layer is isolated from the embedded layer (32). When light (50) is applied to the photodiode, a hole (52) generated in the depletion layer which is formed between the embedded layer (32) and the other base layer (36) moves into the other base layer (36) disposed adjacent to or in the vicinity of the depletion layer, and becomes a photocurrent. The photodiode thus arranged has a high quantum efficiency and has a structure suitable for high-speed operation.

The semiconductor region (31, 37), the embedded layer (32), and the other base layer (36) should preferably have respective dopant concentrations selected to cause a space between the embedded layer (32) and the other base layer (36) to serve as a depletion layer in its entirety.

Preferably, the photodiode further comprises a guard ring (16, 38) made of a semiconductor of the first conductivity type (p or n type). The guard ring (16, 38) is formed in contact with the surface of the semiconductor region (1,7, 31, 33) and isolated from the base layer (11, 36) and the leader (9, 35). The guard ring surrounds the base layer (11, 36) and the leader (9, 35). The guard ring (16, 38) has an impurity concentration selected to electrically substantially separate a portion of the surface of the semiconductor region (1, 7, 31, 33) outside of the guard ring (16, 38) from the base layer (11, 36) and the leader (9, 35). The photodiode is thus electrically separated from other devices (not shown) on the semiconductor substrate (1).

According to the present invention, there is also provide a method of manufacturing a photodiode, comprising the steps of forming, within a semiconductor region (1, 7, 31, 33) having a first conductivity type (p or n type), an embedded layer (2, 32) having a second conductivity type (n or p type) different from the first conductivity type (p or n type), and forming a leader (9, 35) having the second conductivity type (n or p type). The embedded layer (2, 32) extends parallel to a surface (8, 34) of the semiconductor region (1, 7, 31, 33). The leader (9, 35) extends from the surface (8, 34) of the semiconductor region (1, 7, 31, 33) along the depth of the semiconductor region(1, 7, 31, 33), and is joined to a region of the embedded layer (2, 32). The photodiode thus fabricated has a high quantum efficiency with the interior of the semiconductor region(1, 7, 31, 33) being depleted.

The step of forming the embedded layer (2) comprises the step of forming the embedded layer (2) in a region of a surface (3) of a first semiconductor portion (1) having the first conductivity type (p or n type), and forming a second semiconductor portion (7) having the first conductivity type (p or n type) in joined relationship to the first semiconductor portion (1) and the embedded layer (2). In this manner, the embedded layer (2) can be formed according to a simple process.

It is preferable to form a base layer (11) made of a semiconductor having the second conductivity type (n or p type), in the surface (8) of the semiconductor region (1, 7). The base layer (11) is isolated from the embedded layer (2) and joined to the leader (9). The photodiode thus fabricated has a high quantum efficiency with the depletion layer extending from the surface of the semiconductor region (1, 7) along the depth of the semiconductor region.

At least one second embedded layer (13) having the second conductivity type (n or p type) may be formed within the semiconductor region (1, 7) having the first conductivity type (p or n type). The second embedded layer (13) is isolated from the embedded layer (2) and extends parallel to the surface (8) of the semiconductor region (1, 7). The leader (9) is joined to a region of the second embedded layer (13). This arrangement further increases the volume of the depletion layer for an increased quantum efficiency.

The method may further comprise the step of forming another base layer (36) made of a semiconductor having the first conductivity type (p or n type), in the surface (34) of the semiconductor region (31, 33). The other base layer (36) is isolated from the embedded layer (32).

For detecting light, the second guard ring (16) is grounded, and a positive voltage is applied to the leader (9). The positive voltage is of such a magnitude which is determined to cause the space between the base layer (11) and the embedded layer (2) to serve as a depletion layer in its entirety. The region between the base layer (11) and the embedded layer (2) is thus depleted for a high quantum efficiency.

The above and other objects, features, and advantages of the present invention will become apparent from the following description based on the accompanying drawings which illustrate examples of preferred embodiments of the present invention.

### BRIEF DESCRIPTION OF THE DRAWINGS

FIG. 1 is a view showing a structure of a known photodiode;

FIG. 2 is a cross-sectional view of a photodiode according to a first embodiment of the present invention;

FIG. 3 is a cross-sectional view showing a stage after the formation of embedded layer 2 in a process of fabricating the photodiode according to the first embodiment;

FIG. 4 is a cross-sectional view showing a stage after the formation of epitaxial layer 7 in the process of fabricating the photodiode according to the first embodiment;

FIG. 5 is a cross-sectional view showing a stage after the formation of photoresist layer 25 directly above regions where a leader and a first guard ring will not be formed, in the process of fabricating the photodiode according to the first embodiment;

FIG. 6 is a cross-sectional view showing a stage after the injection of phosphorus into regions where the leader and the first guard ring will be formed, in the process of fabricating the photodiode according to the first embodiment;

FIG. 7 is a cross-sectional view showing a stage after the assembly is annealed at a high temperature subsequently to the injection of phosphorus, in the process of fabricating the photodiode according to the first embodiment;

FIG. 8 is a cross-sectional view showing a stage after the formation of photoresist layer 27 directly above regions other than a region where second guard ring 16 will be formed, in the process of fabricating the photodiode according to the first embodiment;

FIG. 9 is a cross-sectional view showing a stage after the formation of second guard ring 16, in the process of fabricating the photodiode according to the first embodiment;

FIG. 10 is a cross-sectional view showing a stage after the formation of photoresist layer 28 directly above regions other than a region where base layer 11 will be formed, in the process of fabricating the photodiode according to the first embodiment;

FIG. 11 is a cross-sectional view showing a stage after the formation of base layer 11, in the process of fabricating the photodiode according to the first embodiment;

FIG. 12 is a cross-sectional view showing a stage after the formation of first interlayer insulating film 18, first interconnection layer 19, and first plug 20, in the process of fabricating the photodiode according to the first embodiment;

FIG. 13 is a cross-sectional view of a photodiode according to a second embodiment of the present invention;

FIG. 14 is a cross-sectional view showing a stage after the formation of first epitaxial layer 7a in a process of fabricating the photodiode according to the second embodiment;

FIG. 15 is a cross-sectional view showing a stage after the formation of second embedded layer 13 in the process of fabricating the photodiode according to the second embodiment;

FIG. 16 is a cross-sectional view showing a stage after the formation of second epitaxial layer 7b in the process of fabricating the photodiode according to the second embodiment;

FIG. 17 is a cross-sectional view of a photodiode according to a third embodiment of the present invention;

FIG. 18 is a cross-sectional view showing a stage after the formation of second guard ring 38, in a process of fabricating the photodiode according to the third embodiment;

FIG. 19 is a cross-sectional view showing a stage after the formation of photoresist layer 47 directly above regions other than a region where base layer 36 will be formed, in the process of fabricating the photodiode according to the third embodiment;

FIG. 20 is a cross-sectional view showing a stage after the formation of base layer 36, in the process of fabricating the photodiode according to the third embodiment;

FIG. 21 is a cross-sectional view illustrative of the manner in which the photodiode according to the first embodiment operates; and

FIG. 22 is a cross-sectional view illustrative of the manner in which the photodiode according to the third embodiment operates.

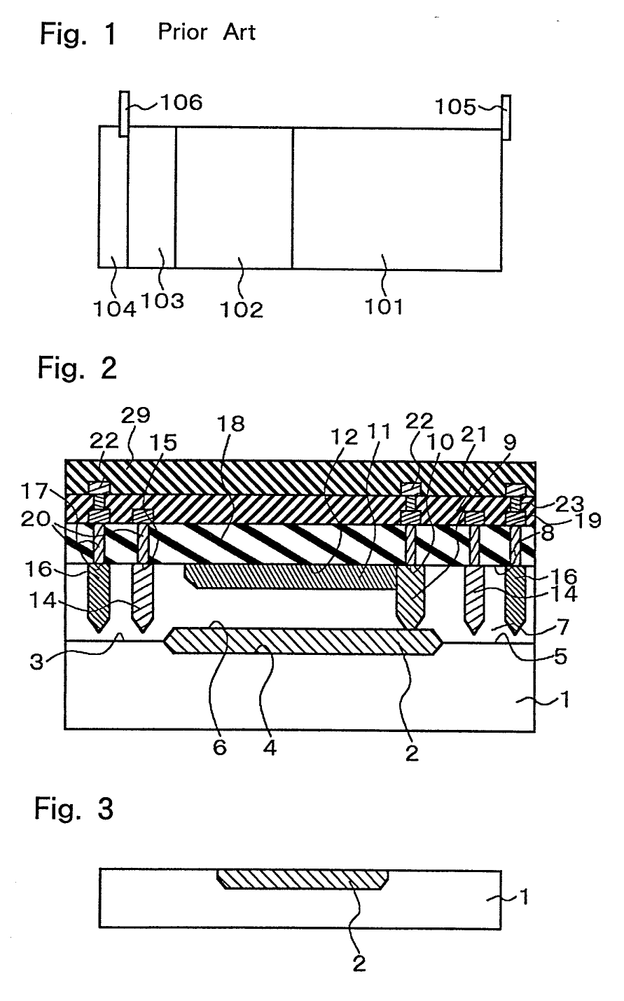

### DETAILED DESCRIPTION OF THE PREFERRED EMBODIMENTS

As shown in FIG. 2, a photodiode according to a first embodiment of the present invention has embedded layer 2 joined to substrate 1.

Substrate 1 is made of a semiconductor having a first conductivity type which represents a p-type conductivity. Substrate 1 has a dopant concentration of about 1×10¹⁵ cm⁻³. Substrate 1 has first surface 3 on its face side that includes first face 4 and second face 5. First face 4 defines an area where an essential photodiode portion will be formed.

Embedded layer 2 is joined to substrate 1 with first face 4 interposed therebetween and shared thereby. Embedded layer 2 is made of a semiconductor having a second conductivity type which is different from the first conductivity type, i.e., represents an n-type conductivity. Embedded layer 2 has a dopant concentration of about 1×10¹⁸ cm⁻³. Embedded layer 2 has third face 6.

While the first conductivity type represents a p-type conductivity and the second conductivity type represents an n-type conductivity in the present embodiment, the first conductivity type may represent an n-type conductivity and the second conductivity type may represent a p-type conductivity.

Epitaxial layer 7 is joined to substrate 1 with second face 5 interposed therebetween and shared thereby, and is also joined to embedded layer 2 with third face 6 interposed therebetween and shared thereby. Epitaxial layer 7 has second surface 8 on its face side which extends parallel to second face 5. The distance from second surface 8 to embedded layer 2 is determined dependent on the absorption coefficient with respect to light to be detected. If epitaxial layer 7 has an absorption coefficient α with respect to light to be detected, then the distance from second surface 8 to embedded layer 2 is represented by 1/α or greater. Epitaxial layer 7 has a thickness selected in the range from 10 to 20 μm. Epitaxial layer 7 is made of a p-type semiconductor, and has a dopant concentration that is lower than the dopant concentration of embedded layer 2. The dopant concentration of epitaxial layer 7 is about 1 ×10¹⁵ cm⁻³ that is the same as the dopant concentration of substrate 1.

Leader 9 is formed in a region of epitaxial layer 7. Leader 9 has fourth face 10 that forms part of second surface 8 of epitaxial layer 7. Leader 9 extends from fourth face 10 vertically along the depth of epitaxial layer 7 and is joined to an area of embedded layer 2. Leader 9 is made of an n-type semiconductor and has a dopant concentration of about 2×10¹⁸ cm⁻³.

Base layer 11 is also formed in a region of epitaxial layer 7. Base layer 11 has fifth face 12 that forms part of second surface 8 of epitaxial layer 7. Base layer 11 is positioned vertically upwardly of embedded layer 2, and extends substantially parallel to embedded layer 2. Base layer 11 is joined to leader 9 and electrically connected thereto. Base layer 11 is made of an n-type semiconductor and has a dopant concentration of about 2×10¹⁸ cm⁻³.

Each pair of substrate 1 and embedded layer 2, embedded layer 2 and epitaxial layer 7, leader 9 and epitaxial layer 7, and epitaxial layer 7 and base layer 11 provides a pn junction, forming a depletion layer in the vicinity of the junction surface thereof. The dopant concentrations of embedded layer 2, epitaxial layer 7, and base layer 11 are not limited to the above numerical values, but may be selected to cause the space between embedded layer 2 and base layer 11 to serve as a depletion layer in its entirety.

First guard ring 14 is formed in a region of epitaxial layer 7 in surrounding relationship to base layer 11 and leader 9. First guard ring 14 is isolated from base layer 11 and leader 9. First guard ring 14 has sixth face 15 that forms part of second surface 8 of epitaxial layer 7. First guard ring 14 is made of an n-type semiconductor and has a dopant concentration of about 2×10^{18 cm}⁻³.

Second guard ring 16 is formed in a region of epitaxial layer 7 in surrounding relationship to first guard ring 14 in ring form. Second guard ring 16 is isolated from first guard ring 14. Second guard ring 16 is made of a p-type semiconductor, and serves as a ground terminal of the photodiode. Holes that are generated when light is detected by the photodiode are drawn from second guard ring 16. Second guard ring 16 serves to separate the photodiode from other devices (not shown) disposed on the semiconductor substrate. Second guard ring 16 has a dopant concentration that is selected to separate the device from other devices. Specifically, second guard ring 16 has a dopant concentration of about 2×10¹⁸ cm⁻³.

First interlayer insulating film 18, first interconnection layer 19, and first plug 20 are formed on second surface 8 of epitaxial layer 7. First interlayer insulating film 18 is a multilayer film comprising an SiO₂ layer and an SiN layer. However, first interlayer insulating film 18 may comprise a single-layer film of SiO₂. Leader 9, first guard ring 14, and second guard ring 16 are connected to first interconnection layer 19 by first plug 20.

Second interlayer insulating film 21, second interconnection layer 22, and second plug 23 are formed on first interlayer insulating film 18 and first interconnection layer 19. Second plug 23 connects first interconnection layer 19 and second interconnection layer 22 to each other. A passivated layer 29 is formed on second interlayer insulating film 21 and second interconnection layer 22.

The photodiode according to the first embodiment detects light with a pn junction which comprises epitaxial layer 7 as a p-type semiconductor and base layer 11 and leader 9 as an n-type semiconductor. For detecting light, second guard ring 16 is grounded, and a positive voltage is applied to leader 9 and first guard ring 14. The positive voltage is of such a magnitude which is determined to cause the space between embedded layer 2 and base layer 11 to serve as a depletion layer in its entirety. A reverse bias is applied to the pn junction. The applied light is detected based on a photocurrent that flows when the bias is applied.

In the first embodiment, first guard ring 14 may be dispensed with. The photodiode thus modified can be manufactured according to a simpler fabrication process. Furthermore, base layer 11 may also be dispensed with. The photodiode which is free of base layer 11 has a reduced quantum efficiency, but can be manufactured according to a simpler fabrication process.

In the first embodiment, the p-type semiconductor may be replaced with n-type semiconductor, and the n-type semiconductor may be replaced with p-type semiconductor. In addition, the second interlayer insulating film, second interconnection layer, and second plug may be dispensed with. Alternatively, one or more sets of an interlayer insulating film and an interconnection layer may be formed on the second interlayer insulating film and the second interconnection layer.

Successive steps of a fabrication process of manufacturing the photodiode according to the first embodiment are shown in FIGS. 3 through 12.

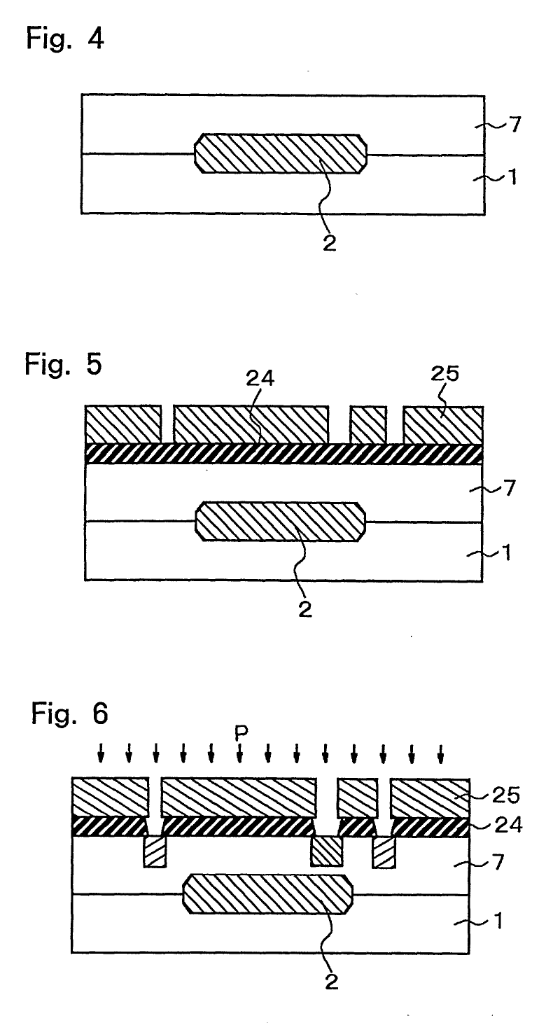

As shown in FIG. 3, a dopant of arsenic is injected into an area of substrate 1 of p-type semiconductor, forming embedded layer 2 therein. Embedded layer 2 has a dopant concentration of about 2×10¹⁸ cm⁻³. Then, as shown in FIG. 4, epitaxial layer 7 is grown on substrate 1 and embedded layer 2. Epitaxial layer 7 is made of a p-type semiconductor, and has a dopant concentration of about 1×10¹⁵ cm⁻³.

Thereafter, silicon oxide film 24 is grown on epitaxial layer 7 to a thickness of about 3000 Å. Then, a photoresist is coated and exposed. Specifically, as shown in FIG. 5, photoresist layer 25 is formed directly above regions where leader 9 and first guard ring 14 will not be formed.

Thereafter, using photoresist layer 25 as a mask, silicon oxide film 24 is etched to form openings in regions where leader 9 and first guard ring 14 will be formed. Then, as shown in FIG. 6, using silicon oxide film 24 and photoresist layer 25, a dopant of phosphorus is injected into the regions where leader 9 and first guard ring 14 will be formed, at such a rate that the concentration of phosphorus in leader 9 and first guard ring 14 is about 2×10¹⁸ cm⁻³.

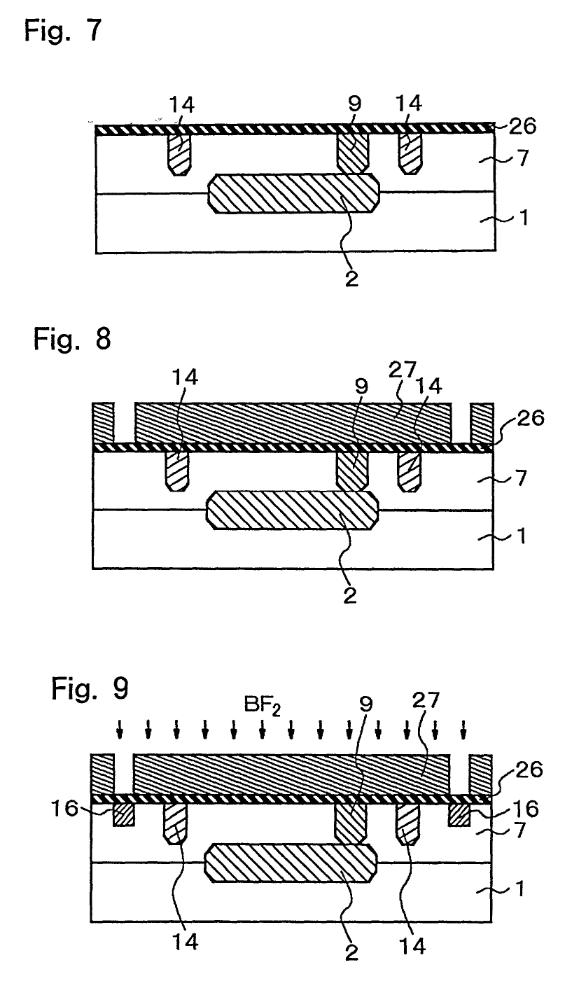

Thereafter, photoresist layer 25 and silicon oxide film 24 are successively removed. Then, as shown in FIG. 7, silicon oxide film 26 is formed on epitaxial layer 7 to a thickness of about 300 Å. Silicon oxide film 26 serves to reduce damage caused upon the injection of an impurity. Subsequently, the assembly is annealed at a high temperature, forming leader 9 and first guard ring 14 as shown in FIG. 7.

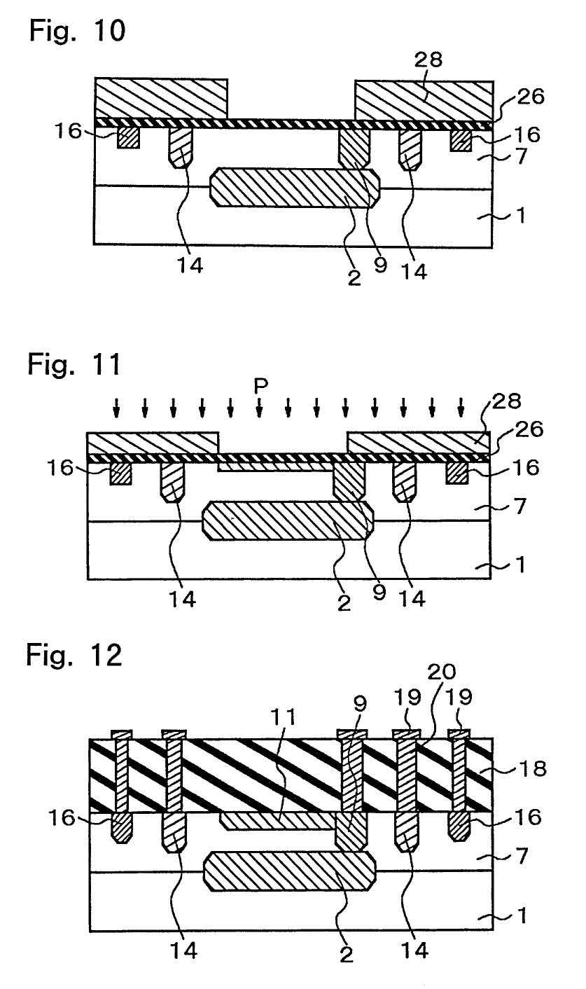

Then, a photoresist is coated and exposed. Specifically, as shown in FIG. 8, photoresist layer 27 is formed directly above regions other than a region where second guard ring 16 will be formed. Thereafter, using photoresist layer 27 as a mask, BF₂ is injected into epitaxial layer 7 to form second guard ring 16 as shown in FIG. 9. BF₂ is injected at such a rate that the concentration of boron in second guard ring 16 is about 2 ×10¹⁸ cm⁻³. Then, a photoresist is coated and exposed. Specifically, as shown in FIG. 10, photoresist layer 28 is formed directly above regions other than a region where base layer 11 will be formed. Thereafter, using photoresist layer 28 as a mask, phosphorus is injected into epitaxial layer 7 to form base layer 11 as shown in FIG. 11. Phosphorus is injected at such a rate that the concentration of phosphorus in base layer 11 is about 2× 10¹⁸ cm⁻³. Then, photoresist layer 28 and silicon oxide film 26 are successively removed.

Thereafter, as shown in FIG. 12, a process of forming interconnections, which is well known in the fabrication of semiconductor devices, is carried out. Specifically, first interlayer insulating film 18 of silicon oxide, first plug 20 of tungsten, and first interconnection layer 19 of aluminum are successively formed. Similarly, second interlayer insulating film 21, second plug 23, and second interconnection layer are successively formed. Thereafter, passivated layer 29 is formed, thus completing the fabrication of the photodiode according to the first embodiment.

The photodiode according to the first embodiment has a quantum efficiency which is about twice the quantum efficiency of the conventional photodiodes. Specifically, when light is applied to the photodiode, the depletion layer produces electron and hole pairs as a photocurrent which is detected as representing the applied light. The depletion layer of the photodiode according to the first embodiment has a larger volume than the depletion layer of the conventional photodiode, resulting in an increased quantum efficiency.

The reasons for the increased volume of the depletion layer are as follows: According to the first reason, the photodiode has embedded layer 2. The presence of embedded layer 2 allows the interior of epitaxial layer 7 and substrate 1 to be used as a depletion layer. The second reason in that the impurity concentration of substrate 1 is low. Since the impurity concentration of substrate 1 is low, no impurity is diffused from substrate 1 into epitaxial layer 7 even when the assembly is processed at a high temperature in the fabrication process. Therefore, any impurity concentration of epitaxial layer 7 is kept at a low level, which is effective in increasing the width of the depletion layer.

As described above, the photodiode according to the first embodiment has a large quantum efficiency. The process of manufacturing the photodiode according to the first embodiment permits the fabrication of a photodiode having a large quantum efficiency.

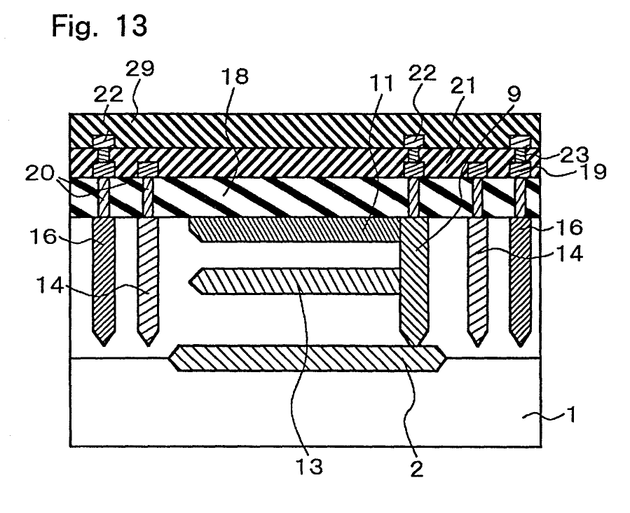

A photodiode according to a second embodiment of the present invention will be described below. The photodiode according to the second embodiment has a structure similar to the structure of the photodiode according to the first embodiment. The photodiode according to the second embodiment differs from the photodiode according to the first embodiment in that, as shown in FIG. 13, second embedded layer 13 is disposed between embedded layer 2 and base layer 11. Second embedded layer 13 extends parallel to the surface of epitaxial layer 7 and is joined to leader 9. The photodiode according to the second embodiment may alternatively have a plurality of second embedded layers 13 each joined to leader 9.

A fabrication process of manufacturing the photodiode according to the second embodiment will be described below.

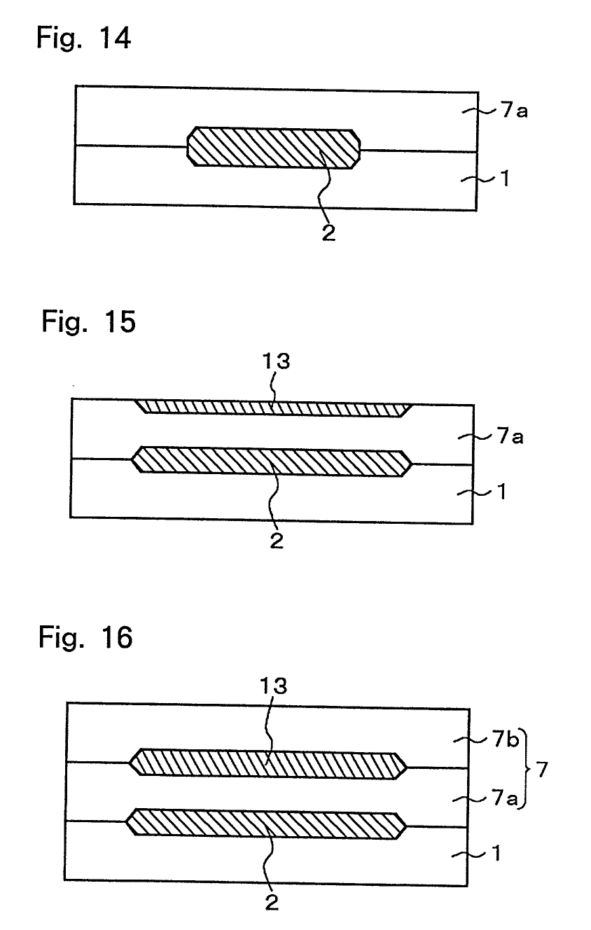

A dopant of arsenic is injected into an area of substrate 1 of p-type semiconductor, forming embedded layer 2 therein. A cross-sectional structure achieved after embedded layer 2 is identical to that shown in FIG. 3. Embedded layer 2 has a dopant concentration of about 1×10¹⁸ cm⁻³. Then, as shown in FIG. 14, first epitaxial layer 7a is grown on substrate 1 and embedded layer 2. First epitaxial layer 7a is made of a p-type semiconductor, and has a dopant concentration of about 1 ×10¹⁵ cm⁻³.

A dopant of arsenic is injected into an area of first epitaxial layer 7a, forming second embedded layer 13 therein as shown in FIG. 15. Second embedded layer 13 has a dopant concentration of about 2×10¹⁸ cm⁻³. Then, as shown in FIG. 16, second epitaxial layer 7b is grown on first epitaxial layer 7a and second embedded layer 13. First epitaxial layer 7a and second epitaxial layer 7b jointly make up epitaxial layer 7.

Remaining steps of the fabrication process of manufacturing the photodiode according to the second embodiment are identical to those of the fabrication process of manufacturing the photodiode according to the first embodiment. That is, the steps ranging from the step of forming leader 9 and first guard ring 14 to the step of forming passivated layer 29 in the fabrication process of manufacturing the photodiode according to the first embodiment are carried out. The photodiode according to the second embodiment is manufactured according to the above fabrication process.

In the second embodiment, the photodiode may have a plurality of embedded layers 13. For forming a plurality of embedded layers 13, the step of forming first epitaxial layer 7a and the step of forming second embedded layer 13 are repeated as many times as the number of desired embedded layers 13. Each of second embedded layers 13 extends parallel to the surface of epitaxial layer 7, is isolated from embedded layer 2 and base layer 11, and is joined to leader 9.

In the photodiode according to the second embodiment, second embedded layer 13 also contributes to an increase in the volume of the depletion layer for an additionally increased quantum efficiency. The process of manufacturing the photodiode according to the second embodiment allows the fabrication of a photodiode having a depletion layer with an increased volume and an increased quantum efficiency.

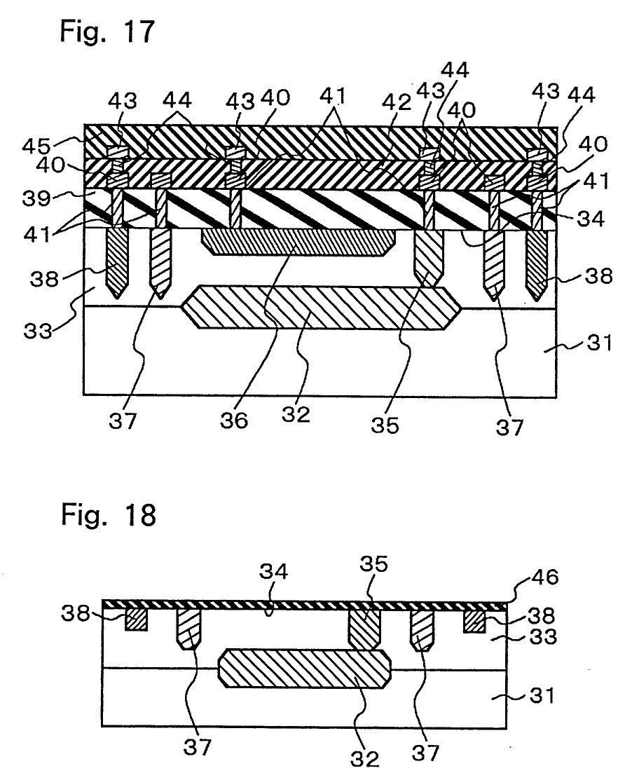

A photodiode according to a third embodiment of the present invention will be described below. FIG. 17 shows a structure of the photodiode according to the third embodiment.

The photodiode according to the third embodiment has a structure which is essentially the same as the structure of the photodiode according to the first embodiment. The photodiode according to the third embodiment differs from the photodiode according to the first embodiment in that whereas base layer 11 of the photodiode according to the first embodiment is made of an n-type semiconductor, base layer 36 of the photodiode according to the third embodiment is made of a p-type semiconductor. The photodiode according to the third embodiment will be described below.

The photodiode according to the third embodiment has substrate 31 made of a semiconductor of p-type conductivity and having a dopant concentration of about 1 ×10¹⁵ cm⁻³. The dopant concentration of substrate 31 is positively lowered of the same reason as described in the first embodiment.

Embedded layer 32 is formed in joined relationship to substrate 31. Embedded layer 32 has an n-type conductivity and has a dopant concentration of about 2× 10¹⁸ cm⁻³.

Epitaxial layer 33 is formed in joined relationship to substrate 31 and embedded layer 32. Epitaxial layer 33 has surface 34 on its face side which extend parallel to the surface of substrate 31 and embedded layer 32. The distance from surface 34 to embedded layer 32 is determined dependent on the absorption coefficient of epitaxial layer 33 with respect to light to be detected. If epitaxial layer 33 has an absorption coefficient α with respect to light to be detected, then the distance from surface 34 to embedded layer 32 is represented by 1/α or greater. As a result, the thickness of epitaxial layer 33 is selected in the range from 10 to 20 μm. Epitaxial layer 33 is made of a p-type semiconductor, and has a dopant concentration that is lower than the dopant concentration of embedded layer 32. The dopant concentration of epitaxial layer 33 is about 1×10¹⁵ cm⁻³ that is the same as the dopant concentration of substrate 31.

Leader 35 is formed in epitaxial layer 33. Leader 35 extends from surface 34 vertically along the depth of substrate 31 and is joined to an area of embedded layer 32. Leader 35 is made of an n-type semiconductor and has a dopant concentration of about 2×10¹⁸ cm⁻³.

Base layer 36 is also formed in epitaxial layer 33. Base layer 36 is held against surface 34 of epitaxial layer 33. Base layer 36 is positioned vertically upwardly of embedded layer 32, and extends substantially parallel to embedded layer 32.

Base layer 36 is made of a p-type semiconductor and has a dopant concentration of about 2×10¹⁸ cm⁻³. Base layer 36 is not joined to leader 35, unlike the photodiode according to the first embodiment in which base layer 11 and leader 9 are joined to each other.

Each pair of substrate 31 and embedded layer 32, embedded layer 32 and epitaxial layer 33, and leader 35 and epitaxial layer 33 provides a pn junction, forming a depletion layer in the vicinity of the junction surface thereof. The space between embedded layer 32 and base layer 36 serves as a depletion layer substantially in its entirety.

The dopant concentrations of embedded layer 32 and epitaxial layer 33 are selected to cause the space between embedded layer 32 and base layer 36 to serve as a depletion layer substantially in its entirety. The dopant concentrations of embedded layer 32 and epitaxial layer 33 are not limited to the above numerical values, but should preferably be selected to cause the space between embedded layer 32 and base layer 36 to serve as a depletion layer substantially in its entirety.

First guard ring 37 is formed in epitaxial layer 33. First guard ring 37 is held against surface 34 of epitaxial layer 33 in surrounding relationship to leader 35 and base layer 36. First guard ring 37 is isolated from leader 35 and base layer 36. First guard ring 37 is made of an n-type semiconductor and has a dopant concentration of about 2×10¹⁸ cm⁻³.

Second guard ring 38 is formed in epitaxial layer 33 in surrounding relationship to first guard ring 37. Second guard ring 38 is isolated from first guard ring 37. Second guard ring 38 is made of a p-type semiconductor. Holes that are generated when light is detected by the photodiode are drawn from second guard ring 38. Second guard ring 38 serves to separate the photodiode from other devices (not shown) disposed on the semiconductor substrate. Second guard ring 38 has a dopant concentration that is selected to separate itself from other devices. Specifically, second guard ring 38 has a dopant concentration of about 2×10¹⁸ cm⁻³.

First interlayer insulating film 39, first interconnection layer 40, and first plug 41 are formed on epitaxial layer 33. First interlayer insulating film 39 is a multilayer film comprising an SiO₂ layer and an SiN layer. However, first interlayer insulating film 39 may comprise a single-layer film of SiO₂. Leader 35, base layer 36, first guard ring 37, and second guard ring 38 are connected to first interconnection layer 40 by first plug 41.

Second interlayer insulating film 42, second interconnection layer 43, and second plug 44 are formed on first interlayer insulating film 39 and first interconnection layer 40. Second plug 44 connects first interconnection layer 40 and second interconnection layer 43 to each other. A passivated layer 45 is formed on second interlayer insulating film 42 and second interconnection layer 43.

The photodiode according to the third embodiment detects light with a pn junction which comprises epitaxial layer 33 and base layer 36 as a p-type semiconductor and embedded layer 32 and leader 35 as an n-type semiconductor. For detecting light, base layer 36 is grounded, and a positive voltage is applied to leader 35. The positive voltage is of such a magnitude which is determined to cause the space between embedded layer 32 and base layer 36 to serve as a depletion layer in its entirety. A reverse bias is applied to the pn junction. The applied light is detected based on a photocurrent that flows when the bias is applied.

A fabrication process of manufacturing the photodiode according to the third embodiment will be described below. The fabrication process of manufacturing the photodiode according to the third embodiment is essentially the same as the fabrication process of manufacturing the photodiode according to the first embodiment, but differs therefrom with respect to the step of forming a base layer.

As shown in FIG. 18, embedded layer 32, epitaxial layer 33, leader 35, first guard ring 37, second guard ring 38, and silicon oxide film 46 are formed on substrate 31 in the same manner as with the fabrication process of manufacturing the photodiode according to the first embodiment. Silicon oxide film 46 which covers epitaxial layer 33 serves to reduce damage caused upon the injection of an impurity. The steps of forming embedded layer 32, epitaxial layer 33, leader 35, first guard ring 37, second guard ring 38, and silicon oxide film 46 are identical to those of the fabrication process of manufacturing the photodiode according to the first embodiment, and will not be described below.

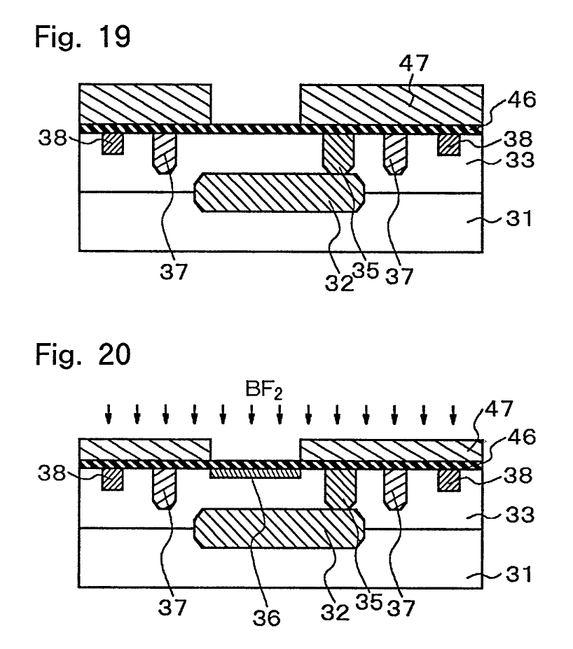

Then, a photoresist is coated and exposed. Specifically, as shown in FIG. 19, photoresist layer 47 is formed directly above regions other than a region where base layer 36 will be formed. Unlike the first embodiment, photoresist layer 47 is formed so as to cover leader 35. As a result, base layer 36 is formed so as to be separate from leader 35.

Thereafter, as shown in FIG. 20, using photoresist layer 47 as a mask, BF₂ is injected into epitaxial layer 33 to form base layer 36. BF₂ is injected at such a rate that the concentration of boron in base layer 36 is about 2×10¹⁸ cm⁻³. Then, photoresist layer 47 and silicon oxide film 46 are successively removed.

Thereafter, as with the first embodiment, a process of forming interconnections is carried out, thus completing the fabrication of the photodiode according to the third embodiment which has the structure shown in FIG. 17.

The photodiode according to the third embodiment has a high quantum efficiency because it has a depletion layer of a large volume as with the photodiodes according to the first and second embodiments. Specifically, the interior of depletion layer 33 and substrate 31 can be used as a depletion layer, and the impurity concentration of substrate 31 is low. Therefore, no impurity is diffused from substrate 31 into epitaxial layer 33 even when the assembly is processed at a high temperature in the fabrication process. Therefore, any impurity concentration of epitaxial layer 33 is kept at a low level, which is effective in increasing the width of the depletion layer.

The photodiode according to the third embodiment has a higher response speed than the photodiodes according to the first and second embodiments. The reasons for the higher response speed will be described below.

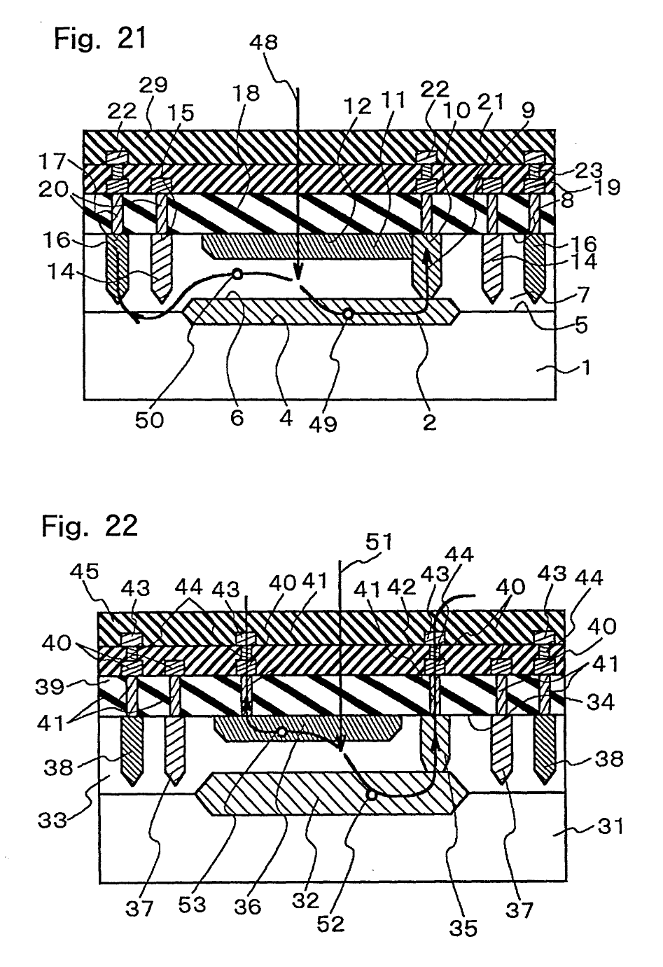

When light 48 is applied to the photodiodes according to the first and second embodiments, as shown in FIG. 21, electron 49 and hole 50 are generated in the depletion layer formed in the space between embedded layer 2 and base layer 11. Electron 49 moves into embedded layer 2, and becomes a photocurrent. In order for hole 50 to become a photocurrent, hole 50 needs to move from the space between embedded layer 2 and base layer 11 to second guard ring 16. Therefore, hole 50 must move a longer distance than electron 49.

When light 51 is applied to the photodiode according to the third embodiment, as shown in FIG. 22, electron 52 and hole 53 are generated in the depletion layer formed in the space between embedded layer 32 and base layer 36. As with the first and second embodiments, electron 52 moves into embedded layer 32 and becomes a photocurrent. Hole 53 moves into base layer 36 adjacent to the depletion layer and becomes a photocurrent, unlike the first and second embodiments. Therefore, hole 52 moves a shorter distance. As a result, the response speed of the photodiode according to the third embodiment is higher than the response speed of the photodiodes according to the first and second embodiments.

According to the third embodiment, therefore, the photodiode has a high quantum efficiency and a high response speed.

It is to be understood, however, that although the characteristics and advantages of the present invention have been set forth in the foregoing description, the disclosure is illustrative only, and changes may be made in the arrangement of the parts within the scope of the appended claims.

What is claimed is:

1. A photodiode comprising:
a semiconductor region having a first conductivity type;
an embedded layer disposed in said semiconductor region and having a second conductivity type different from said first conductivity type; and
a leader made of a semiconductor of the second conductivity type;
said embedded layer extending parallel to a surface of said semiconductor region;
said leader extending from the surface of said semiconductor region along the depth of said semiconductor region, and being joined to a region of said embedded layer.

2. A photodiode according to claim 1, further comprising:
a base layer made of a semiconductor of the second conductivity type;
said base layer being held against the surface of said semiconductor region and extending parallel to the surface of said semiconductor region, said base layer being isolated from said embedded layer and electrically connected to said leader.

3. A photodiode according to claim 2, wherein said semiconductor region, said embedded layer, and said base layer have respective dopant concentrations selected to cause a space between said embedded layer and said base layer to serve as a depletion layer in its entirety.

4. A photodiode according to claim 2, further comprising:
at least one second embedded layer having the second conductivity type;
said second embedded layer being disposed in said semiconductor region and extending parallel to the surface of said semiconductor region, said second embedded layer being isolated from said embedded layer and said base layer and joined to said leader.

5. A photodiode according to claim 4, wherein said semiconductor region, said embedded layer, said second embedded layer, and said base layer have respective dopant concentrations selected to cause a space between said embedded layer and said second embedded layer, a space between a plurality of said second embedded layers, and a space between said second embedded layer and said base layer to serve as depletion layers in their entirety.

6. A photodiode according to claim 2, further comprising:
another base layer made of a semiconductor of the first conductivity type;
said other base layer being held against the surface of said semiconductor region and extending parallel to the surface of said semiconductor region, said other base layer being isolated from said embedded layer.

7. A photodiode according to claim 6, wherein said semiconductor region, said embedded layer, and said other base layer have respective dopant concentrations selected to cause a space between said embedded layer and said other base layer to serve as a depletion layer in its entirety.

8. A photodiode according to claim 1, further comprising:
a guard ring made of a semiconductor of the first conductivity type;
said guard ring being formed in the surface of said semiconductor region and isolated from said leader, said guard ring surrounding said leader;
said guard ring having an impurity concentration selected to electrically and substantially separate a portion of the surface of said semiconductor region outside of said guard ring from said leader.

9. A photodiode according to claim 2, further comprising:
a guard ring made of a semiconductor of the first conductivity type;
said guard ring being formed in the surface of said semiconductor region and isolated from said base layer and said leader, said guard ring surrounding said base layer and said leader;
said guard ring having an impurity concentration selected to electrically and substantially separate a portion of the surface of said semiconductor region outside of said guard ring from said base layer and said leader.

10. A photodiode according to claim 4, further comprising:
a guard ring made of a semiconductor of the first conductivity type;
said guard ring being formed in the surface of said semiconductor region and isolated from said leader, said guard ring surrounding said leader;
said guard ring having an impurity concentration selected to electrically and substantially separate a portion of the surface of said semiconductor region outside of said guard ring from said leader.

11. A photodiode according to claim 6, further comprising:
a guard ring made of a semiconductor of the first conductivity type;
said guard ring being formed in the surface of said semiconductor region and isolated from said base layer and said leader, said guard ring surrounding said base layer and said leader;
said guard ring having an impurity concentration selected to electrically and substantially separate a portion of the surface of said semiconductor region outside of said guard ring from said base layer and said leader.

12. A photodiode according to claim 1, wherein the distance between the surface of said semiconductor region and said embedded layer is determined depending on an absorption coefficient with respect to light applied to said semiconductor region.

13. A photodiode according to claim 12, wherein said distance is represented by 1/α where α represents said absorption coefficient.

14. A method of manufacturing a photodiode, comprising the steps of:
forming, within a semiconductor region having a first conductivity type, an embedded layer having a second conductivity type different from said first conductivity type; and
forming a leader having the second conductivity type;
said embedded layer extending parallel to the surface of said semiconductor region;
said leader extending from the surface of said semiconductor region along the depth of said semiconductor region, and being joined to a region of said embedded layer.

15. A method according to claim 14, wherein said step of forming the embedded layer comprises the step of:
forming said embedded layer in a region of a surface of a first semiconductor portion having said first conductivity type; and
forming a second semiconductor portion having said first conductivity type in joined relationship to said first semiconductor portion and said embedded layer.

16. A method according to claim 14, further comprising the step of:
forming a base layer made of a semiconductor having said second conductivity type, in the surface of said semiconductor region;
said base layer being isolated from said embedded layer and joined to said leader.

17. A method according to claim 14, further comprising the step of:
forming, within the semiconductor region having the first conductivity type, at least one second embedded layer having the second conductivity type;
said second embedded layer being isolated from said embedded layer and extending parallel to the surface of said semiconductor region;
said leader being joined to a region of said second embedded layer.

18. A method according to claim 16, further comprising the step of:
forming, within the semiconductor region having the first conductivity type, at least one second embedded layer having the second conductivity type;
said second embedded layer being isolated from said embedded layer and extending parallel to the surface of said semiconductor region;
said leader being joined to a region of said second embedded layer.

19. A method according to claim 16, further comprising the step of:
forming another base layer made of a semiconductor having the first conductivity type, in the surface of said semiconductor region;
said other base layer being isolated from said embedded layer.

20. A method according to claim 16, further comprising the step of:
forming a guard ring made of a semiconductor having the first conductivity type;
said guard ring having a surface disposed on a surface of said semiconductor region and being isolated from said base layer and said leader, said guard ring surrounding said base layer and said leader;
said guard ring having an impurity concentration selected to electrically and substantially separate a portion of the surface of said semiconductor region outside of said guard ring from said base layer and said leader.
